(19) United States
(12) Patent Application Publication
(10) Pub. No.: US 2016/0099387 A1
(43) Pub. Date: Apr. 7, 2016

(54) SEMICONDUCTOR LIGHT EMITTING DEVICE

(71) Applicant: SAMSUNG ELECTRONICS CO., LTD., Suwon-si (KR)

(72) Inventors: Tsuyoshi TSUTSUI, Suwon-si (KR); Jong Cheol KIM, Suwon-si (KR); Il Woo PARK, Suwon-si (KR); Jin Hyun LEE, Suwon-si (KR)

(21) Appl. No.: 14/718,252

(22) Filed: May 21, 2015

(30) Foreign Application Priority Data
Oct. 6, 2014 (KR) 10-2014-0134144

(51) Int. Cl. H01L 33/50; H01L 33/60

(52) U.S. Cl. CPC H01L 33/502; H01L 33/60

(57) ABSTRACT

A semiconductor light emitting device includes a package body having first and second surfaces being opposed to each other, first and second external terminal blocks disposed in opposite end portions of the package body, respectively, and having portions exposed to surfaces of the package body, respectively. A wavelength converting material layer is disposed between the first and second external terminal blocks and has a first surface substantially coplanar with the first surface of the package body, and a second surface opposing the first surface of the wavelength converting material layer. A LED chip is disposed package body on at least a portion of the second surface of the wavelength converting material layer between the first and second external terminal blocks within the package body.

### CROSS-REFERENCE TO RELATED APPLICATION

This application claims priority under 35 U.S.C. §119 to Korean Patent Application No. 10-2014-0134144 filed on Oct. 6, 2014, with the Korean Intellectual Property Office, the entire disclosure of which is incorporated herein by reference.

### BACKGROUND

The present disclosure relates to a semiconductor light emitting device.

Conventionally, a light emitting device provided with a light emitting diode (LED) chip has employed a package structure having a case obtained by injection-molding a white resin into a lead frame. Such a light emitting device may have an LED chip mounted in a groove portion of the case so as to be connected to the lead frame, and the groove portion may be filled with a resin. In particular, in order to manufacture a white light emitting device, a phosphor may be included in the resin filling the groove portion.

However, an LED package using such a lead frame is inappropriate for miniaturization, and since the case as well as the lead frame, needs to be injection-molded, yields are reduced, and manufacturing costs may be increased.

Recently, lead frame-free LED packages have been developed. In a case in which a wavelength converting material layer is applied to a surface of such an LED package, light is leaked through side surfaces of the wavelength converting layer, and as a result, effective light efficiency in a desired direction may be decreased.

### SUMMARY

An aspect of the present disclosure relates to a semiconductor light emitting device capable of enhancing effective light efficiency in a desired direction by preventing light leakage through the use of a wavelength converting material layer.

According to an example embodiment of the present disclosure, a semiconductor light emitting device may include a package body having first and second surfaces opposed to each other, and a plurality of side surfaces disposed therebetween, first and second external terminal blocks disposed in opposite end portions of the package body, respectively, and each having a portion exposed to surfaces of the package body, a wavelength converting material layer disposed between the first and second external terminal blocks, and having a first surface substantially coplanar with the first surface of the package body, and a second surface opposing the first surface of the wavelength converting material layer, and a semiconductor light emitting diode (LED) chip disposed between the first and second external terminal blocks within the package body, disposed on at least a portion of the second surface of the wavelength converting material layer, and electrically connected to the first and second external terminal blocks.

The package body may include a transparent resin substance containing high reflectivity particles.

The high reflectivity particles may include at least one selected from the group consisting of titanium oxide (TiO₂), aluminum oxide (Al₂O₃), niobium oxide (Nb₂O₅), and zinc oxide (ZnO).

The wavelength converting material layer may contain a phosphor or a quantum dot (QD).

The wavelength converting material layer may be a sintered body film formed of a ceramic phosphor.

The wavelength converting material layer may have a plate shape having a predetermined thickness.

Side surfaces of the semiconductor LED chip may be encapsulated by the package body.

The first and second external terminal blocks may each have a first surface exposed to the first surface of the package body, a second surface opposing the first surface of the external terminal block and disposed within the package body, and side surfaces disposed between the first and second surfaces of the external terminal block and having at least one thereof exposed to the side surface of the package body.

The first and second external terminal blocks may each include an insulating block body, and a conductive via passing through first and second surfaces of the insulating block body and disposed on the exposed side surface of the external terminal block.

The exposed side surfaces of the respective external terminal blocks may be disposed on the same surface of the package body.

A connector of each of the first and second external terminal blocks may further include an electrode layer disposed on the first surface of the insulating block body and connected to the conductive via.

The semiconductor LED chip and the external terminal block may be connected to one another by a wire, and the wire is disposed within the package body.

The first, second, and side surfaces of the package body may be provided in a parallelepipedal structure having six planes.

The semiconductor LED chip may be a blue LED chip, and the wavelength converting material layer is configured so as to emit white light as final light.

According to an example embodiment of the present disclosure, a semiconductor light emitting device may include a reflective package body having first and second surfaces opposed to each other, and a plurality of side surfaces disposed therebetween, first and second external terminal blocks disposed on opposite end portions of the package body, respectively, and each having a portion exposed to surfaces of the package body, a semiconductor LED chip disposed between the first and second external terminal blocks within the package body, and electrically connected to the first and second external terminal blocks, and a wavelength converting material layer having a plate shape having an area greater than an area of the semiconductor LED chip, having a surface substantially coplanar with the first surface of the package body so as to be exposed through the first surface of the package body. The semiconductor LED chip may be interposed between the wavelength converting material layer and the package body

The other remaining surfaces of the semiconductor LED chip aside from one surface of the semiconductor LED chip may be encapsulated by the package body.

The semiconductor LED chip may be a nanostructure semiconductor LED chip.

The first and second external terminal blocks may have a structure having a step facing the semiconductor LED chip.

According to an example embodiment of the present disclosure, a semiconductor light emitting device may include a package body including reflective particles, first and second external terminal blocks disposed in opposite end portions of the package body, respectively, and each exposed to at least one of a side surface and a bottom surface of the package body, a semiconductor light emitting diode (LED) chip disposed between the first and second external terminal blocks within the package body, and connected to the first and second external terminal blocks by wires; and a wavelength converting material layer having a plate shape having a predetermined thickness, and having a surface substantially coplanar with a top surface of the package body so as to be exposed through a first surface of the package body, and in contact with a surface of the semiconductor LED chip.

According to an example embodiment of the present disclosure, a semiconductor light emitting device may include a semiconductor light emitting diode (LED) chip, a wavelength converting material layer disposed on the LED chip, a package body having a recess which is recessed from a first surface of the package body and accommodates the LED chip and the wavelength converting material layer, a surface of the wavelength converting material layer and the first surface of the package body being substantially coplanar with each other, and first and second external terminal blocks disposed in opposite end portions of the package body and electrically connected to first and second electrodes of the LED chip, respectively. First and second sidewalls of the recess may be disposed between the first and second external terminal blocks and the wavelength converting material layer, respectively.

The package body may include a lateral surface intersected by the first surface of the package body. The lateral surface and external surfaces of the first and second external terminal blocks may be substantially coplanar with each other.

The first and second external terminal blocks may be flush to opposite ends of the package body, respectively.

The first and second external terminal blocks each may include a conductive via electrically connected to one of the first and second electrodes of the LED chip, and an insulating block body interposed between the conductive via and one of the first and second sidewalls of the recess.

The package body may include a transparent resin substance containing high reflectivity particles.

According to an example embodiment of the present disclosure, a lighting apparatus may include a semiconductor light emitting device according to the examples, a driving unit configured to drive the semiconductor light emitting device, and an external connection unit configured to supply an external voltage to the driving unit.

### BRIEF DESCRIPTION OF DRAWINGS

The above and other aspects, features and advantages of the present disclosure will be more clearly understood from the following detailed description taken in conjunction with the accompanying drawings, in which:

FIGS. 1 and 2 are a top view and a side cross-sectional view each illustrating a semiconductor light emitting device according to an example embodiment in the present disclosure,

FIGS. 3 through 7 are views respectively illustrating main processes of a method of manufacturing the semiconductor light emitting device illustrated in FIG. 1,

FIG. 8 is a top view illustrating an array of FIG. 4,

FIG. 9 is a top view illustrating a semiconductor light emitting device according to an example embodiment in the present disclosure,

FIG. 10 is a perspective view illustrating an external terminal block applicable to an example embodiment in the present disclosure,

FIG. 11 is a schematic perspective view illustrating a wafer on which a semiconductor light emitting diode (LED) epitaxial layer is grown,

FIG. 12 is a flowchart illustrating a process of selecting a semiconductor LED chip and a wavelength converting material layer,

FIG. 13 is a CIE 1931 color space diagram illustrating a wavelength converting material applicable to an example embodiment in the present disclosure,

FIGS. 14 through 16 are views illustrating various examples of a semiconductor LED chip applicable to an example embodiment in the present disclosure,

FIGS. 17 and 18 are a top view and a side cross-sectional view each illustrating a semiconductor light emitting device according to an example embodiment in the present disclosure,

FIG. 19 is a view illustrating a state in which a semiconductor light emitting device is mounted on a circuit substrate according to an example embodiment in the present disclosure,

FIGS. 20 and 21 are cross-sectional views illustrating examples of backlight units using semiconductor light emitting devices according to example embodiments in the present disclosure,

FIG. 22 is an exploded perspective view illustrating an example of a lighting apparatus using a semiconductor light emitting device according to an example embodiment in the present disclosure, and

FIG. 23 is a view illustrating an example of a headlamp using a semiconductor light emitting device according to an example embodiment in the present disclosure.

### DETAILED DESCRIPTION

Hereinafter, example embodiments in the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements. In the present disclosure, terms such as “top surface,” “tip part,” “end portion,” “lower surface,” “below,” “side surface,” and the like, are determined based on the drawings, and in actuality, the terms may be changed according to a direction in which a light emitting device is disposed in actuality.

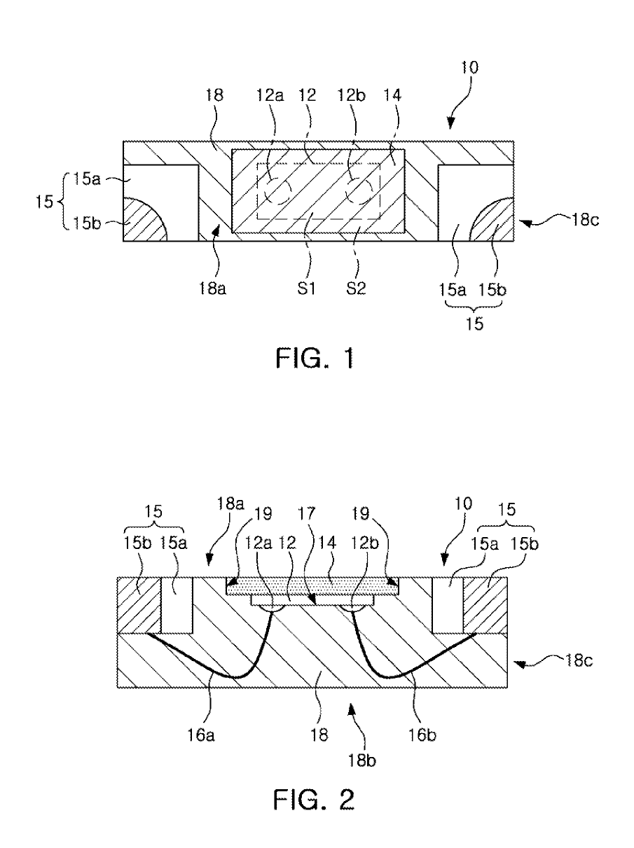

FIGS. 1 and 2 are a top view and a side cross-sectional view each illustrating a semiconductor light emitting device according to an example embodiment in the present disclosure.

Referring to FIGS. 1 and 2, a semiconductor light emitting device 10 may include a package body 18, first and second external terminal blocks 15 disposed in opposite end portions of the package body 18, respectively, a wavelength converting material layer 14 disposed between the first and second external terminal blocks 15, and a semiconductor light emitting diode (LED) chip 12.

The package body 18 may have a parallelepipedal structure. Here, first and second surfaces 18a and 18b of the package body 18 may be surfaces disposed in a lengthwise direction thereof. In the present example embodiment, the first and second surfaces 18a and 18b and a side surface 18c of the package body 18 may be a flat surface. As necessary, at least one surface of the package body 18 may have an uneven surface through an additional processing process.

The package body 18 may be formed of a transparent resin including high reflectivity particles in order to reduce loss due to light absorption by other components. The hig reflectivity particles may include an electrically insulating material. Such high reflectivity particles may be reflective metal particles or white ceramic particles. For example, the white ceramic particles may include at least one of titanium oxide (TiO₂), aluminum oxide (Al₂O₂), niobium oxide (Nb₂O₅), and zinc oxide (ZnO).

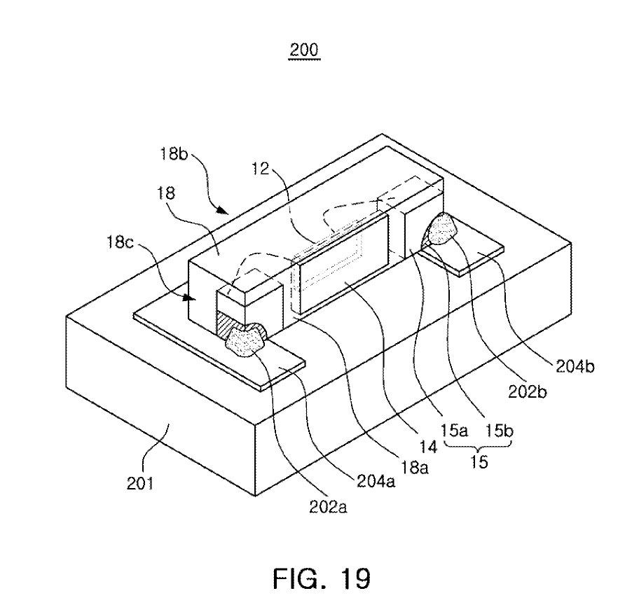

The first and second external terminal blocks 15 may be disposed in opposite end portions of the package body 18, respectively. Although the first and second external terminal blocks 15 are disposed within the package body 18, each of the first and second external terminal blocks 15 may have at least one surface thereof exposed outwardly. In the present example embodiment, the first and second external terminal blocks 15 may each have a first surface exposed to the first surface 18a of the package body 18, a second surface opposing the first surface of the external terminal block 15 and facing the first surface 18a of the package body 18. The package body 18 may have a recess 17 which may be recessed from the first surface 18a of the package body 18 and accommodate the LED chip 12 and the wavelength converting material layer 14. First and second sidewalls 19 of the recess 17 may be disposed between the first and second external terminal blocks 15 and the wavelength converting material layer 14, respectively. The external terminal block 15 used in the present example embodiment may include an insulating block body 15a, and an electrical connection part 15b having a form similar to that of a via structure penetrating through the first and second surfaces of the external terminal block 15. The electrical connection part 15b may be exposed through two adjacent side surfaces of the package body 18. Side surfaces of the respective first and second external terminal blocks 15 to which the electrical connection parts 15b are exposed may be disposed on the same surface of the package body 18. In the present example embodiment, two electrical connection parts 15b may be exposed through the first surface 18a of the package body 18 and a same side surface of the package body 18 disposed in the lengthwise direction. The light emitting device 10 having such a structure may be efficiently used as a side view light emitting LED package structure as illustrated in FIG. 19. The first and second external terminal blocks 15 may have various forms.

In the present example embodiment, the wavelength converting material layer 14 may be disposed between the first and second external terminal blocks 15, and may be disposed so as to be in contact with the first surface 18a of the package body 18. The wavelength converting material layer 14 may be a layer containing a material converting at least a portion of light generated by the semiconductor LED chip 12 into light having a different wavelength. For example, the wavelength converting material layer 14 may be a layer containing a wavelength converting material such as a phosphor and/or a quantum dot (QD), more particularly, a transparent resin layer containing a phosphor. In a specific example, the wavelength converting material layer 14 may be a sintered body formed of a ceramic phosphor.

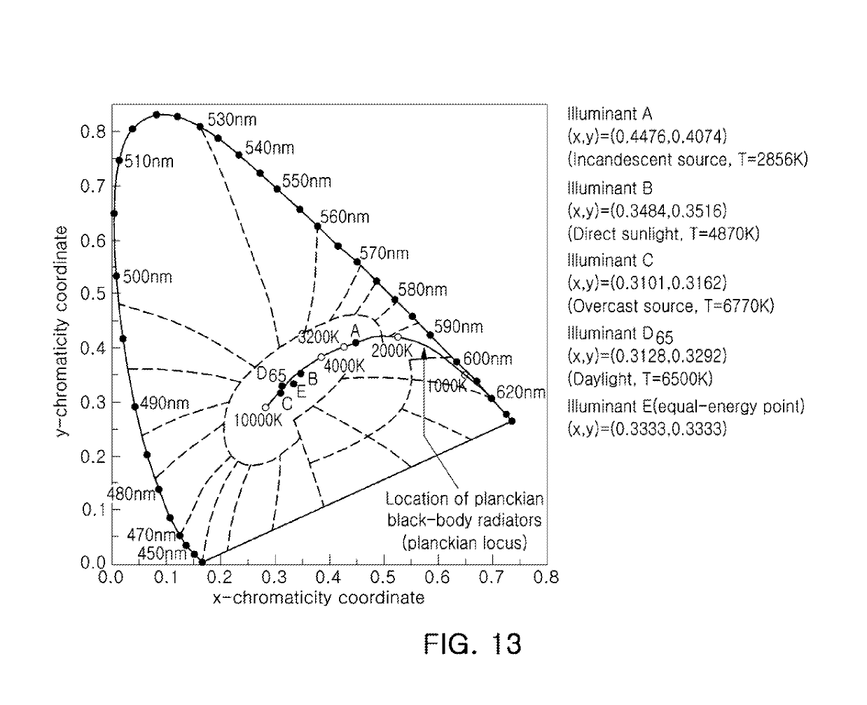

The wavelength converting material layer 14 may contain one or more wavelength converting materials based on a wavelength of the semiconductor LED chip 12. For example, the semiconductor LED chip 12 may emit blue light, and the wavelength converting material layer 14 may be configured to emit white light as final light. Such wavelength converting materials used in the present example embodiment will be described in greater detail with reference to FIG. 13.

As illustrated in FIG. 2, the wavelength converting material layer 14 may have a plate shape having a predetermined thickness. Under the assumption that both surfaces of the wavelength converting material layer 14 facing one another are referred to as first and second surfaces, the first surface of the wavelength converting material layer 14 may be substantially coplanar with the first surface 18a of the package body 18 so as to be exposed thereto. The semiconductor LED chip 12 may be disposed on the second surface of the wavelength converting material layer 14.

The semiconductor LED chip 12 may be disposed between the first and second external terminal blocks 15 within the package body 18. The wavelength converting material layer 14 may have an area the same as an area S1 of the semiconductor LED chip 12, or an area S2 greater than the area S1 of the semiconductor LED chip 12. First and second electrodes 12a and 12b of the semiconductor LED chip 12 may be electrically connected to the first and second external terminal blocks 15, respectively, more particularly, to the electrical connection parts 15b. As in the present example embodiment, such a connection may be obtained by wires 16a and 16b. The wires 16a and 16b and areas connected to the wires 16a and 16b may be disposed within the package body 18 so as to be protected therein.

In a manner dissimilar to that of the present example embodiment, the external terminal block 15 may be modified in various manners to be directly connected to at least one of the electrodes 12a and 12b without using the wire.

As such, light generated by the semiconductor LED chip 12 may pass through the wavelength converting material layer 14 to be emitted. That is, in the present example embodiment, the wavelength converting material layer 14 of the package body 18 may serve as a light emitting window.

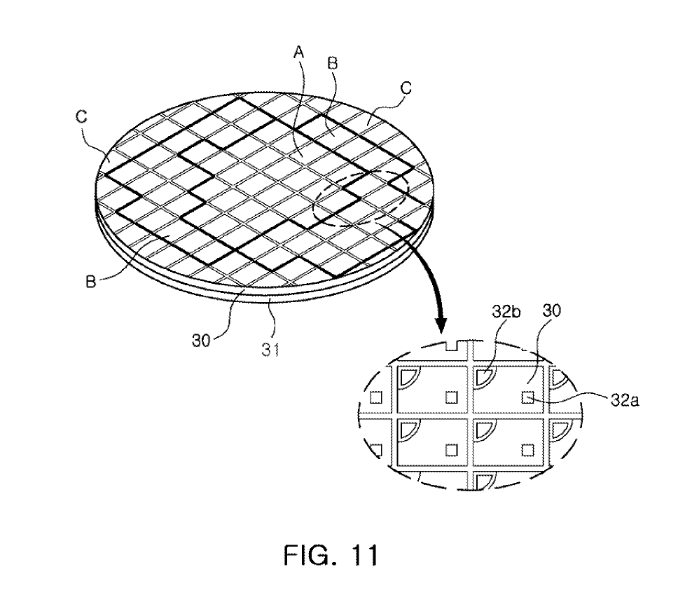

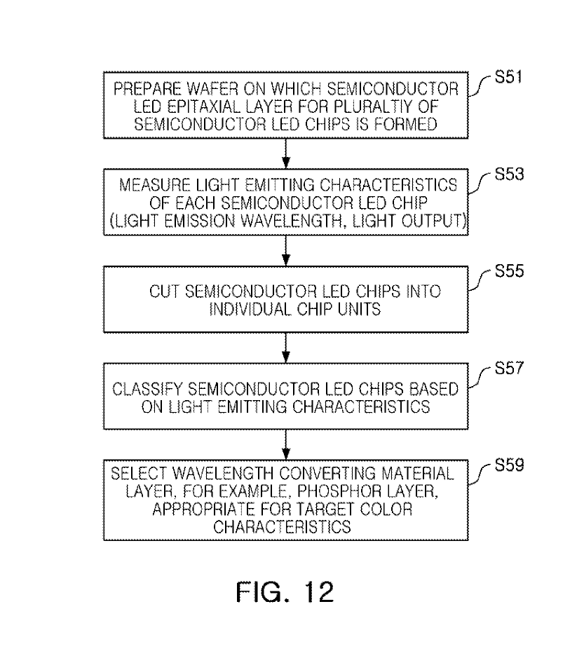

In addition, in an array according to the present example embodiment, since side surfaces of the wavelength converting material layer 14 are not exposed due to being encapsulated by the package body 18, light leakage occurring through the side surfaces of the wavelength converting material layer 14 may be prevented. Further, the semiconductor LED chip 12 may be disposed on a pre-manufactured wavelength converting material layer 14. The wavelength converting material layer 14 of the semiconductor LED chip 12 may not be coated on a surface of the semiconductor LED chip 12 in advance. Instead, the pre-manufactured wavelength converting material layer 14 may be disposed on the semiconductor LED chip 12. As such, through the use of the pre-manufactured wavelength converting material layer 14, a wavelength converting material layer 14 having wavelength converting characteristics appropriate for wavelength characteristics of the semiconductor LED chip 12 may be selected, and thereby light characteristics of target white light may be obtained. A detailed description thereof will be provided with reference to FIGS. 11 and 12.

Since the semiconductor light emitting device 10 according to the present example embodiment does not require an additional case structure or a lead frame, miniaturization thereof may be achieved. Also, since the wavelength converting material layers 14 having appropriate converting characteristics based on light characteristics, for example, a wavelength, or light output, of the semiconductor LED chip 12 may be selected and combined therewith, and the side surfaces of the wavelength converting material layer 14 are not exposed from the package body 18, undesired light leakage may be prevented.

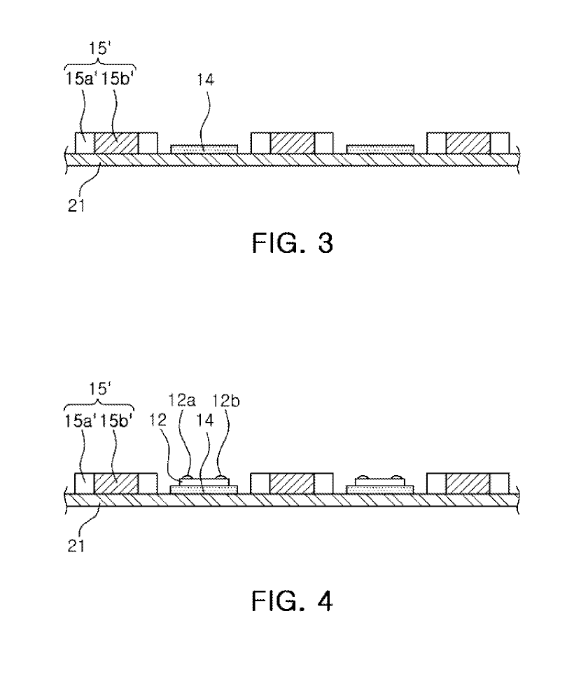

A method of manufacturing the semiconductor light emitting device illustrated in FIGS. 1 and 2 will be described hereinafter. FIGS. 3 through 7 are views respectively illustrating main processes of a method of manufacturing the semiconductor light emitting device illustrated in FIG. 1.

As illustrated in FIG. 3, a plurality of external terminal blocks 15′ may be disposed on a sheet 21, and a wavelength converting material layer 14 may be disposed between the plurality of external terminal blocks 15′ on the sheet 21.

The sheet 21 may have bonding strength in order to support a structure to be disposed on a top surface thereof.

The sheet 21 may be a thermosetting film or an ultraviolet (UV) light-curable film. The wavelength converting material layer 14 may define a light emitting window of a final light emitting device. The wavelength converting material layer 14 may have an area greater than at least that of the semiconductor LED chip 12 of FIG. 4. The wavelength converting material layer 14 may be a resin layer containing a phosphor or a QD, or a sintered body formed of a ceramic phosphor. Such a wavelength converting material layer 14 may be selected in advance so as to have desired final light characteristics, for example, whiteness, based on light characteristics, for example, a peak wavelength, or light output, of the semiconductor LED chip 12 to be used in the present example embodiment. The external terminal block 15′ illustrated in FIG. 3 may include an insulating block body 15a′, and an electrical connection part 15b′ configured of a conductive via penetrating through the insulating block body 15a′ in a manner similar to that of an external terminal block 25 illustrated in FIG. 10. The external terminal block 15a′ may be a material such as an insulating ceramic sintered body, or a printed circuit board (PCB).

As illustrated in FIG. 4, the semiconductor LED chips 12 may be arranged on the wavelength converting material layer 14.

The semiconductor LED chip 12 may be disposed to have a surface on which electrodes 12a and 12b are formed to face upwardly, between the external terminal blocks 15′. In such an array, a surface of the semiconductor LED chip 12 may be in direct contact with the wavelength converting material layer 14. Although the semiconductor LED chip 12 may be bonded onto a surface of the wavelength converting material layer 14, in a case of using a bonding material, a material without optically adverse effects may be selected. In this process, side surfaces of the semiconductor LED chip 12 may be exposed outwardly.

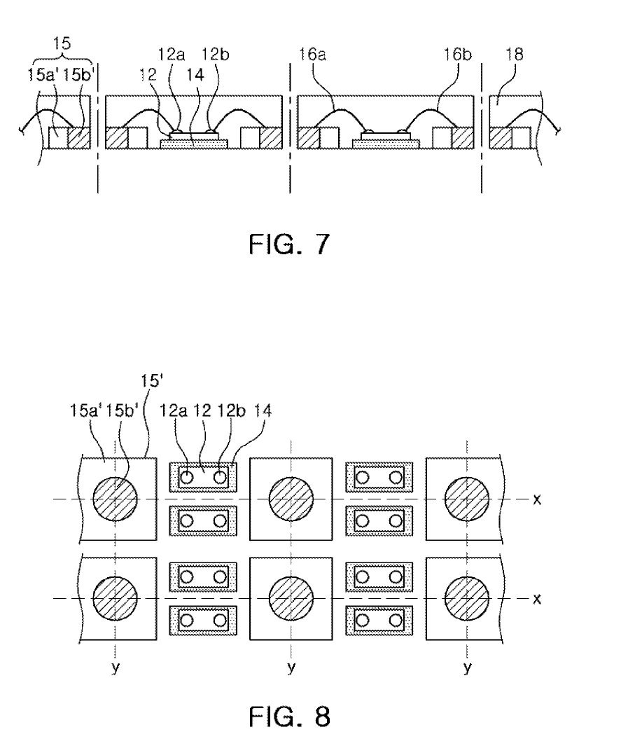

FIG. 8 is a top view illustrating the array of FIG. 4. As illustrated in FIG. 8, four semiconductor LED chips 12 may share a single external terminal block 15′ in the array. The external terminal block 15′ may have an insulating block body 15a′, and an electrical connection part 15b′ formed of a conductive via penetrating through both surfaces of the insulating block body 15a′. The external terminal block 15′ may be cut in x and y directions along dashed lines as indicated in FIG. 8 through a subsequent cutting process with reference to FIG. 7. As illustrated in FIG. 2, the electrical connection part 15b may be exposed to a cut surface of the external terminal block 15 to provide a connection area for a connection to an external circuit.

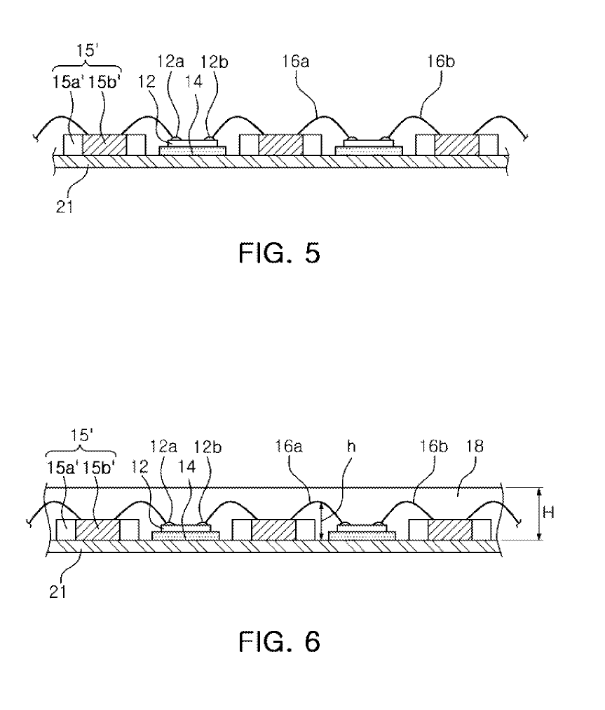

As illustrated in FIG. 5, the electrodes 12a and 12b of the semiconductor LED chip 12 may be connected to the exposed electrical connection parts 15b′ of adjacent external terminal blocks 15′ through wires 16a and 16b, respectively.

As illustrated in FIG. 6, the package body 18 may be formed to encapsulate an area in which the external terminal block 15′ and the semiconductor LED chip 12 are arranged.

The package body 18 may be formed by coating a liquid curable resin and curing the coated liquid curable resin. Such a coating process may be performed by a process selected from among a spin coating process, a spray coating process, a screen printing process, a jet printing process, and an electrophoretic deposition process. The curing resin for the package body 18 may have a height H greater than at least a height h of the wire 16a or 16b. Accordingly, the wires 16a and 16b may be disposed within the package body 18 formed of a resin. The package body 18 may be a transparent resin including high reflectivity particles having electrical insulation characteristics in order to reduce loss due to light absorption by other elements. Such high reflectivity particles may be reflective metal particles or white ceramic particles. The white ceramic particles may include at least one of TiO₂, Al₂O₃, Nb₂O₅, and ZnO.

As illustrated in FIG. 7, a material resulting from such processes may be cut into individual package units so as to obtain a desired semiconductor light emitting device 10. In the top view illustrated in FIG. 8, when the external terminal block 15′ is cut in the subsequent cutting process along the dashed lines, for example, the x and y directions, the electrical connection part 15b′ of the single external terminal block 15′ may be cut into quarters so as to belong to respective individual light emitting devices. In this process, the electrical connection part 15b′ may be exposed to two adjacent side surfaces of the package body 18, and such exposed surfaces may be provided as external connection areas for external terminals with reference to FIGS. 1 and 2. The manner of configuring the external terminal of the light emitting device is not limited thereto, and may also have a different array form, such that two or more chips may share a single external terminal block.

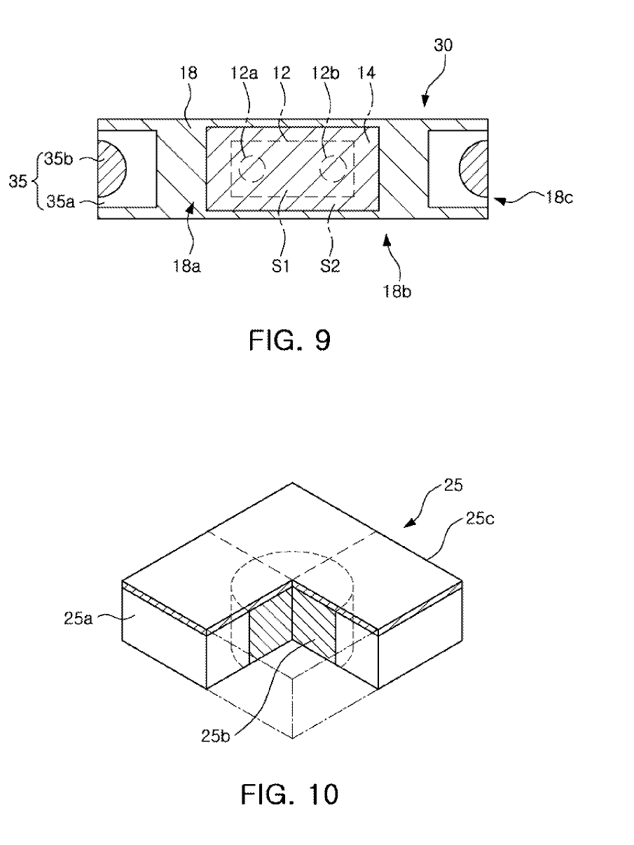

FIG. 9 is a top view illustrating a semiconductor light emitting device obtained two semiconductor LED chips disposed on opposite sides of a single external terminal block.

A semiconductor light emitting device 30 illustrated in FIG. 9 may have a structure similar to that of FIG. 1, and may only differ from FIG. 1 in terms of a shape and disposition of first and second external terminal blocks 35 of FIG. 9. In a manner similar to that of the aforementioned example embodiments, the first and second external terminal blocks 35 may include an insulating block body 35a and a connection part 35b penetrating through the insulating block body 35a. However, the first and second external terminal blocks 35 may have the connection parts 35b exposed to side surfaces of the first and second external terminal blocks 35, respectively, and may each have the connection part 35b having a cylindrical shape, and subsequently to being vertically cut into halves, having a semicircular top surface.

The external terminal block used in the aforementioned example embodiments may be modified in various manners. FIG. 10 is a perspective view illustrating an external terminal block applicable to an example embodiment in the present disclosure.

An external terminal block 25 illustrated in FIG. 10 may have a structure similar to that of the external terminal block 15′ illustrated in FIG. 3. That is, the external terminal block 25 may include an insulating block body 25a, and an electrical connection part 25b configured of a conductive via penetrating through the insulating block body 25a. In addition, the external terminal block 25 may further include an electrode layer 25c disposed on one surface of the insulating block body 25a, and connected to the electrical connection part 25b. For example, the insulating block body 25a may be a PCB such as a flame retardant 4 (FR4), and the electrode layer 25c may be silver (Au)/nickel (Ni)/copper (Cu). The electrode layer 25c may provide a connection surface to which a wire is connected.

Through the process described in FIG. 7, such an external terminal block 25 may be divided into quarters along dashed lines indicated in FIG. 10, and the electrical connection part 25b may be exposed to two adjacent cut surfaces of a final package body.

In the semiconductor light emitting device according to the example embodiment described above, wavelength converting material layers having appropriate converting characteristics based on light characteristics of the semiconductor LED chip, for example, a wavelength, or light output, may be selected and combined therewith. Such a process will be described with reference to FIGS. 11 and 12.

FIG. 11 is a schematic perspective view illustrating a wafer on which a semiconductor LED epitaxial layer is grown.

As illustrated in FIG. 11, a wafer 31 may include a semiconductor LED epitaxial layer 30 for a plurality of semiconductor LED chips. For example, the wafer 31 may be a sapphire substrate, and the semiconductor LED epitaxial layer 30 may be a nitride semiconductor layer for an LED.

In this process, the semiconductor LED epitaxial layer 30 may have a form divided into individual chip C units through isolation etching. The semiconductor LED epitaxial layer 30 divided into each chip unit C may have electrodes 32a and 32b formed thereon. Such electrodes may include a first electrode 32b formed on a first conductivity-type semiconductor layer exposed to a mesa-etched area, and a second electrode 32a formed on a second conductivity-type semiconductor layer.

Although grown in a single wafer 31 through a process performed under an identical condition and within an identical chamber, characteristics of the semiconductor LED chips C may differ from one another based on a wafer area. A chip disposed in a central area A of the wafer may have different light characteristics from light characteristics of chips disposed in respective edge areas B and C of the wafer. For example, in a case in which the wafer illustrated in FIG. 11 is divided into four areas A, B, and C by measuring a light emission wavelength, that is, a peak wavelength, and light output with respect to each of the chips of the wafer, wavelength converting materials, that is, phosphor layers, having different converting characteristics with respect to the chips disposed in the respective four areas may be required in order to obtain target white light.

FIG. 12 is a flowchart illustrating a process of selecting a semiconductor LED chip and a wavelength converting material layer.

As illustrated in FIG. 12, in operation S51, the wafer on which the semiconductor LED epitaxial layer for the plurality of semiconductor LED chips is formed may be provided. In operation S53, light emission characteristics of each semiconductor LED chip disposed on the wafer may be measured.

For example, such light emission characteristics may include at least one of a light emission wavelength, that is, a peak wavelength, and light output. In operation S55, the measured semiconductor LED chips may be cut into individual chip units, and in operation S57, the semiconductor LED chips may be classified based on measured light emission characteristics thereof. Such a chip classification process may be referred to as a “binning” process.

In operation S59, a wavelength converting material layer, for example, a phosphor layer, appropriate for target color characteristics may be selected. For example, in a case in which final target light is white light, the semiconductor LED chip may be a blue LED chip, and a wavelength converting material layer through which white light corresponding to target color coordinates may be obtained may be selected based on pre-classified blue LED chips. In other words, the target white light may be obtained by selecting from among wavelength converting material layers containing phosphors having different types and/or quantities based on the classified blue LED chips, or wavelength converting material layers having different thicknesses.

Based on light emitting characteristics of the semiconductor LED chip and characteristics of final target light, the wavelength converting material applicable to the present example embodiment may be provided in various manners.

FIG. 13 is a CIE 1931 color space diagram illustrating a wavelength converting material applicable to an example embodiment in the present disclosure.

Phosphors or QDs applicable to the present example embodiment may have various compositions and wavelength characteristics. Such phosphors may be ceramic phosphors, and may use oxide-based phosphors, silicate-based phosphors, nitride-based phosphors, and fluoride-based phosphors as follows.

Oxide-based phosphors: yellow and green Y₃Al₅O₁₂:Ce, Tb₃Al₅O₁₂:Ce, Lu₃Al₅O₁₂:Ce

Silicate-based phosphors: yellow and green (Ba,Sr)₂SiO₄:Eu, yellow and orange (Ba,Sr)₃SiO₅:Ce

Nitride-based phosphors: green β-SiAlON:Eu, yellow La₃Si₆N₁₁:Ce, orange α-SiAlON:Eu, red CaAlSiN³:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}N_{18-x-y} (0.5≦x≦3, 0<z<0.3, 0<y≦4), where Ln denotes an element selected from the group consisting of IIIA group elements and rare earth elements, and M denotes at least one element selected from the group consisting of calcium (Ca), barium (Ba), strontium (Sr), and magnesium (Mg).

Fluoride-based phosphors: KSF red K₂SiF₆:Mn4+, K₂TiF₆:Mn⁴⁺, NaYF₄:Mn⁴⁺, NaGdF₄:Mn⁴⁺

In general, phosphor compositions need to conform to Stoichiometric requirements, and each element may be substituted with a different element within the same group in the periodic table of elements. For example, Sr may be substituted with Ba, Ca, Mg, or the like, in the alkaline earth metal group II while yttrium (Y) may be substituted with terbium (Tb), lutetium (Lu), scandium (Sc), gadolinium (Gd), or the like, in the lanthanide group. Also, europium (Eu), or the like, an activator, may be substituted with cerium (Ce), Tb, praseodymium (Pr), erbium (Er), ytterbium (Yb), or the like, based on a desired energy level. In addition, the activator may be used alone, or a co-activator, or the like, may be further included to change characteristics.

Further, a material such as a QD may be used as a phosphor substitute material, or the phosphor and the QD may be used in combination or alone.

The QD may have a structure including a core such as cadmium selenide (CdSe) and indium phosphide (InP) having a diameter of 3 to 10 nanometers (nm), a shell such as zinc sulfide (ZnS) and zinc selenide (ZnSe) having a diameter of 0.5 to 2 nm, and a ligand for stabilizing the core and the shell, and may provide various colors based on the size thereof.

The following Table 1 illustrates types of phosphor materials of a white light emitting device including a UV LED chip (200 nm to 440 nm) or a blue LED chip (440 nm to 480 nm) according to the application fields.

TABLE 1

| Purpose | Phosphor Materials |
|---|---|
| LED TV BLU | β-SiAlON:Eu²⁺, (Ca, Sr)AlSiN₃:Eu²⁺, La₃Si₆N₁₁:Ce³⁺, |
| | K₂SiF₆:Mn⁴⁺, SrLiAl₃N₄:Eu, |
| | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, NaYF₄:Mn⁴⁺, |
| | NaGdF₄:Mn⁴⁺ |
| Lighting | Lu₃Al₅O₁₂:Ce³⁺, Ca-α-SiAlON:Eu²⁺, La₃Si₆N₁₁:Ce³⁺, |
| | (Ca, Sr)AlSiN₃:Eu²⁺, Y₃Al₅O₁₂:Ce³⁺, K₂SiF₆:Mn⁴⁺, |
| | SrLiAl₃N₄:Eu, |
| | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, NaYF₄:Mn⁴⁺, |
| | NaGdF₄:Mn⁴⁺ |
| Side View | Lu₃Al₅O₁₂:Ce³⁺, Ca-α-SiAlON:Eu²⁺, La₃Si₆N₁₁:Ce³⁺, |
| (Mobile, | (Ca, Sr)AlSiN₃:Eu²⁺, Y₃Al₅O₁₂:Ce³⁺, (Sr, Ba, Ca, |
| Laptop PC) | Mg)₂SiO₄:Eu²⁺, K₂SiF₆:Mn⁴⁺, SrLiAl₃N₄:Eu, |
| | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, NaYF₄:Mn⁴⁺, |
| | NaGdF₄:Mn⁴⁺ |
| Electric | Lu₃Al₅O₁₂:Ce³⁺, Ca-α-SiAlON:Eu²⁺, La₃Si₆N₁₁:Ce³⁺, |
| Apparatus | (Ca, Sr)AlSiN₃:Eu²⁺, Y₃Al₅O₁₂:Ce³⁺, K₂SiF₆:Mn⁴⁺, |
| (Vehicle Head | SrLiAl₃N₄:Eu, |
| Lamp, and the | Ln₄₋ₓ(Eu_{z}M_{1-z})ₓSi_{12-y}Al_{y}O_{3+x+y}N_{18-x-y}(0.5 ≦ x ≦ 3, |
| like.) | 0 < z < 0.3, 0 < y ≦ 4), K₂TiF₆:Mn⁴⁺, NaYF₄:Mn⁴⁺, |
| | NaGdF₄:Mn⁴⁺ |

As such, various types of wavelength converting materials, for example, phosphors or QDs, may be used to convert light generated by an active layer. Further, using such wavelength converting materials, white light may be obtained as finally emitted light. The wavelength converting materials may form the wavelength converting material layer used in the example embodiment described above.

For example, the wavelength converting material layer 14 illustrated in FIG. 1 may contain at least one type of phosphor excited by light generated by the semiconductor LED chip 12 so as to emit light having a different wavelength. Accordingly, the emission of light having various colors, including white light, may be controlled.

In a case in which the semiconductor LED chip 12 emits blue light, a wavelength converting material layer containing at least one of yellow, green, and red phosphors may be employed, and white light having various temperatures may be emitted based on a mixing ratio thereof with yellow, green, and red phosphors. Alternatively, a wavelength converting material layer containing green or red phosphors may be applied to the semiconductor LED chip 12.

Also, the wavelength converting material layer may further apply green and/or red phosphors aside from yellow phosphors to the semiconductor LED chip 12, and may adjust a color temperature and a color rendering index (CRI) of white light. In addition, the semiconductor LED chip 12 may be configured to include at least one semiconductor LED chip emitting purple, blue, green, red, or infrared (IR) light. For example, the semiconductor LED chip 12 may adjust a CRI in a range from a level of light emitted by a sodium-vapor (Na) lamp with a CRI of 40, or the like, to a level of sunlight with a CRI of 100 through a combination of appropriate phosphors, and may generate various types of white light having a color temperature in a range of 2,000K to 20,000K.

Referring to the CIE 1931 color space illustrated in FIG. 13, white light generated by combining yellow, green, and red phosphors with the UV LED or the blue LED and/or combining at least one of a green LED and a red LED therewith may have two or more peak wavelengths, and may be positioned in a segment linking (x, y) coordinates of (0.4476, 0.4074), (0.3484, 0.3516), (0.3101, 0.3162), (0.3128, 0.3292), and (0.3333, 0.3333) in the CIE 1931 color space illustrated in FIG. 13. Alternatively, the white light may be positioned in an area surrounded by the segment and a black body radiation spectrum.

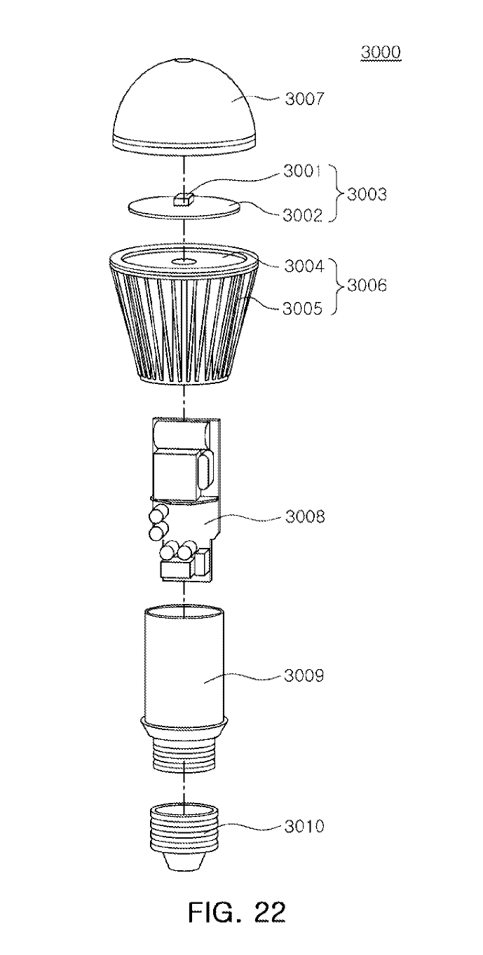

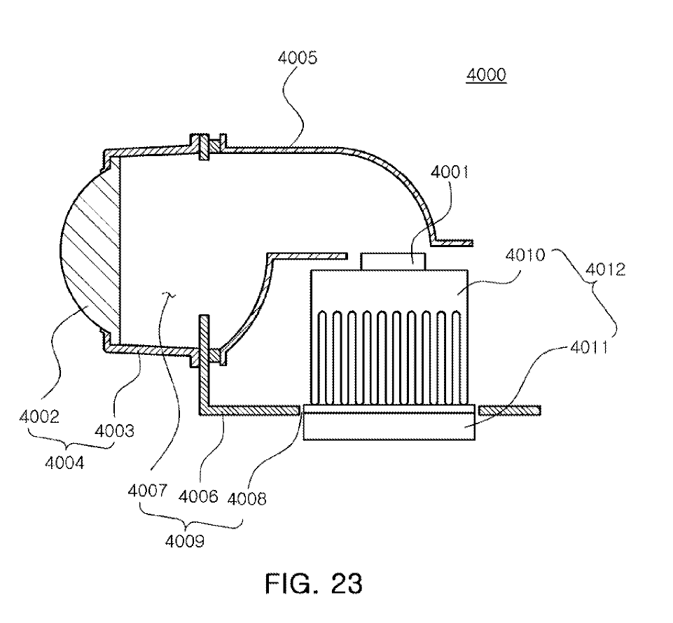

The color temperature of the white light may be in a range of 2,000K to 20,000K. As described above, through the combination of appropriate phosphors, an average color rendering index (Ra) in a range from 85 to 99 may be achieved. Semiconductor light emitting modules having relatively high CRIs may be efficiently utilized in a bulb-type lighting apparatus illustrated in FIG. 22.

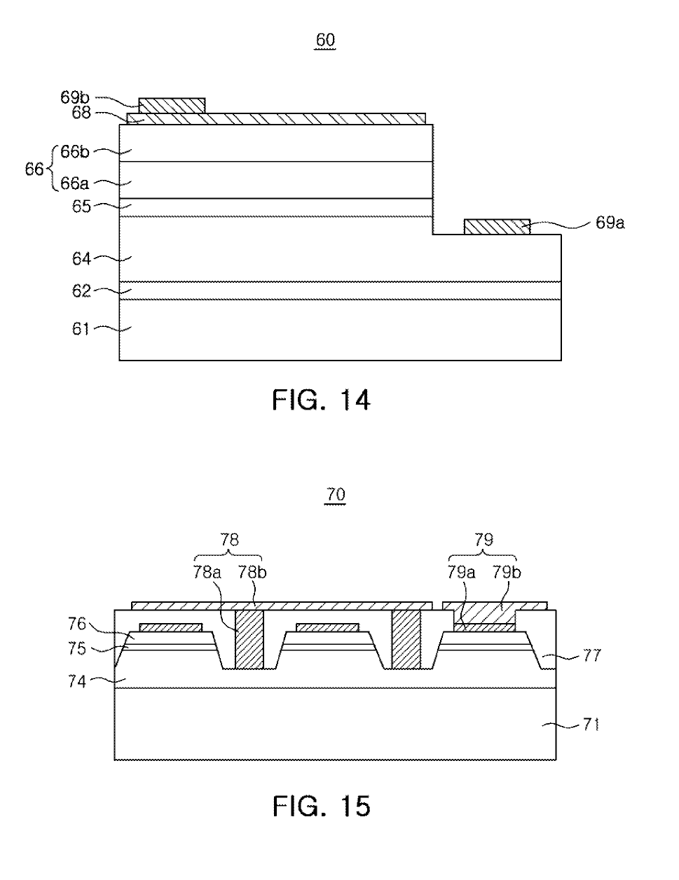

FIGS. 14 through 16 are views illustrating various examples of a semiconductor LED chip applicable to an example embodiment in the present disclosure.

A semiconductor LED chip 60 illustrated in FIG. 14 may include a substrate 61, a first conductivity-type semiconductor layer 64, an active layer 65, and a second conductivity-type semiconductor layer 66 which are sequentially stacked on the substrate 61. A buffer layer 62 may be disposed between the substrate 61 and the first conductivity-type semiconductor layer 64.

The buffer layer 62 may be AlₓIn_{y}Ga_{1-x-y}N, wherein 0≦x≦1, 0≦y≦1. For example, the buffer layer 62 may be aluminum nitride (AlN), aluminum gallium nitride (AlGaN), or indium gallium nitride (InGaN). As necessary, the buffer layer 62 may be formed by combining a plurality of layers, or gradually changing a composition thereof. The substrate 61 used in the present example embodiment may be an insulating substrate, such as a sapphire substrate.

The first conductivity-type semiconductor layer 64 may be a nitride semiconductor satisfying n-type AlₓIn_{y}Ga_{1-x-y}N, wherein 0≦x≦1, 0≦y≦1, 0≦x+y≦1, and n-type impurities therein may be silicon (Si). For example, the first conductivity-type semiconductor layer 64 may include an n-type gallium nitride (GaN). The second conductivity-type semiconductor layer 66 may be a nitride semiconductor satisfying p-type AlₓIn_{y}Ga_{1-x-y}N, wherein 0≦x<1, 0≦y<1, 0≦x+y<1, and p-type impurities therein may be Mg. For example, the second conductivity-type semiconductor layer 66 may have a monolayer structure. As necessary, the second conductivity-type semiconductor layer 66 may also have a multilayer structure having different compositions. As illustrated in FIG. 14, the second conductivity-type semiconductor layer 66 may include a p-type AlGaN layer 66a provided as an electron blocking layer (EBL) and a p-type GaN layer 66b provided as a contact layer.

The active layer 65 may have a multi-quantum well (MQW) structure in which a quantum well layer and a quantum barrier layer are laminated in an alternating manner. For example, the quantum well layer may be InₓGa₁₋ₓN, wherein 0<x≦1, and the quantum barrier layer may be a GaN.

The semiconductor LED chip 60 may include a first electrode 69a disposed on the first conductivity-type semiconductor layer 64, and an ohmic contact layer 68 and a second electrode 69b sequentially disposed on the second conductivity-type semiconductor layer 66.

However, the first electrode 69a and the ohmic contact layer 68 are not limited thereto. The first electrode 69a and the ohmic contact layer 68 may also include a material such as Ag, Ni, Al, rhodium (Rh), palladium (Pd), iridium (Ir), ruthenium (Ru), Mg, zinc (Zn), platinum (Pt), or gold (Au), and may be used as a structure having a monolayer or two or more layers. The first electrode 69a may be a contact electrode layer, and may include chromium (Cr)/Au. The first electrode 69a may further include a pad electrode layer on the contact electrode layer. The pad electrode layer may be an Au layer, Sn layer, or Au/Sn layer.

The ohmic contact layer 68 may be provided in various manners based on a chip structure. In the present example embodiment, since the ohmic contact layer 68 has a structure similar to a flip chip structure, the ohmic contact layer 68 may include Ag. On the other hand, the ohmic contact layer 68 may be formed of a light transmissive electrode. The light transmissive electrode may be one of a transparent conductive oxide layer or a nitride layer. For example, the light transmissive electrode may be at least one selected from indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂ and Zn₍₁₋ₓ₎MgₓO (zinc magnesium oxide), wherein 0≦x≦1. As necessary, the ohmic contact layer 68 may include a graphene layer. The second electrode 69b may include Au, Sn, or Au/Sn.

A semiconductor LED chip 70 illustrated in FIG. 15 may include a substrate 71, a first conductivity-type semiconductor layer 74, an active layer 75, and a second conductivity-type semiconductor layer 76 which are sequentially stacked on the substrate 71.

The semiconductor LED chip 70 may include first and second electrodes 78 and 79 connected to the first conductivity-type semiconductor layer 74 and the second conductivity-type semiconductor layer 76, respectively. The first electrode 78 may include a conductive via 78a penetrating through the second conductivity-type semiconductor layer 76 and the active layer 75 and connected to the first conductivity-type semiconductor layer 74, and a first electrode pad 78b connected to the conductive via 78a. The conductive via 78a may be electrically separated from the active layer 75 and the second conductivity-type semiconductor layer 76 through being enclosed by an insulating layer 77. The conductive via 78a may appropriately adjust a number, a form, a pitch, and a contact area with the first conductivity-type semiconductor layer 74 in order to lower a level of contact resistance. The second electrode 79 may include an ohmic contact layer 79a disposed on the second conductivity-type semiconductor layer 76, and a second electrode pad 79b formed on the ohmic contact layer 79a.

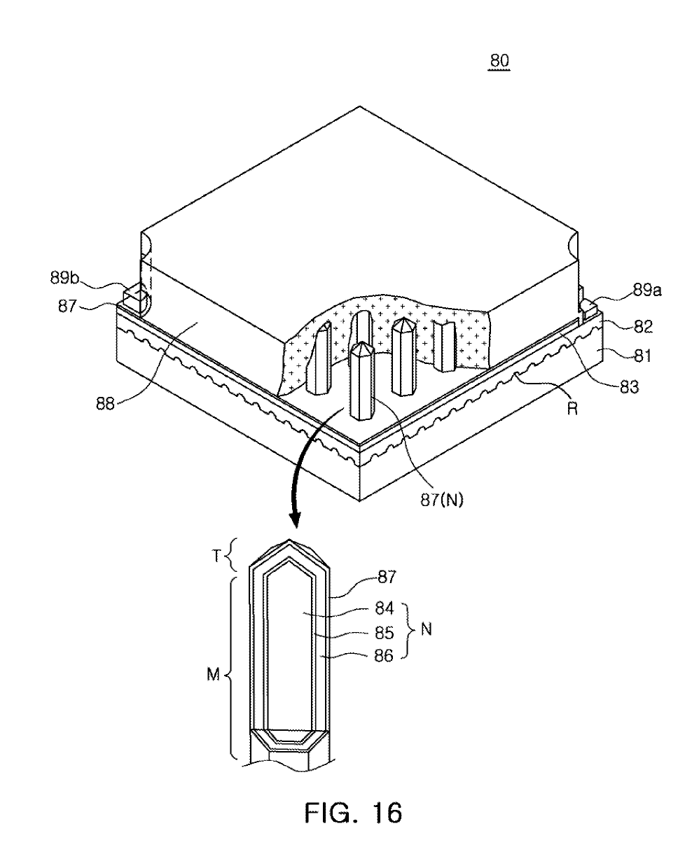

FIG. 16 is a side cross-sectional view illustrating a nanostructure semiconductor LED chip applicable to an example embodiment in the present disclosure.

Referring to FIG. 16, a nanostructure semiconductor LED chip 80 may include a base layer 82 formed of a first conductivity-type semiconductor material, and a plurality of light emitting nanostructures N disposed on the base layer 82.

The nanostructure semiconductor LED chip 80 may include a substrate 81 having a top surface on which the base layer 82 is disposed. An unevenness R may be formed on the top surface of the substrate 81. The unevenness R may serve to enhance quality of a single crystal grown on the substrate 81 while improving light extraction efficiency. The substrate 81 may be an insulating, conductive, or semiconductor substrate. For example, the substrate 81 may be sapphire, silicon carbide (SiC), magnesium aluminate (MgAl₂O₄), magnesium oxide (MgO), lithium aluminate (LiAlO₂), lithium gallium oxide (LiGaO₂), and GaN.

The base layer 82 may include a first conductivity-type nitride semiconductor layer, and may provide a growth surface of the light emitting nanostructure N. For example, the base layer 82 may be an n-type GaN. An insulating film 83 having an opening for growth of the light emitting nanostructure N, more particularly, a nanocore 84, may be formed on the base layer 82. The nanocore 84 may be formed in an area of the base layer 82 exposed through the opening. The insulating film 83 may be used as a mask for growing the nanocore 84. For example, the insulating film 83 may be an insulating material such as SiO₂ or SiNₓ.

The light emitting nanostructure N may include a main part M having a hexagonal pillar structure, and a tip part T disposed on the main part M. Side surfaces of the main part M of the light emitting nanostructure N may have the same crystal plane, and the tip part T of the light emitting nanostructure N may have a different crystal plane from those of the side surfaces of the light emitting nanostructure N. The tip part T of the light emitting nanostructure N may have a hexagonal pyramid structure. Such a division in the structure may be determined by the nanocore 84 in actuality, and the nanocore 84 may be understood as being divided into the main part M and the tip part T.

The light emitting nanostructure N may include the nanocore 84 formed of a first conductivity-type nitride semiconductor, and an active layer 85 and a second conductivity-type nitride semiconductor layer 86 sequentially disposed on the nanocore 84.

The light emitting nanostructure N may include a contact electrode 87 connected to the second conductivity-type nitride semiconductor layer 86. The contact electrode 87 used in the present example embodiment may be formed of a conductive material having light transmissivity. Such a contact electrode 87 may ensure light extraction towards the light emitting nanostructure, that is, towards a direction opposite to the substrate. Although not limited hereto, the contact electrode 87 may be one of a transparent conductive oxide layer and a nitride layer. Otherwise, the contact electrode 87 may be a reflective electrode material.

An insulating protective layer 88 may be formed on a top surface of the light emitting nanostructure N. Such an insulating protective layer 88 may be a passivation layer for protecting the light emitting nanostructure N. In addition, the insulating protective layer 88 may be formed of a material having light transmissivity so as to allow light generated in the light emitting nanostructure N to be extracted therefrom. In this case, the insulating protective layer 88 may enhance light extraction efficiency by selecting a material having an appropriate level of refractive index.

As in the present example embodiment, subsequently to forming the contact electrode 87, spaces between the plurality of light emitting nanostructures N may be filled with the insulating protective layer 88. The insulating protective layer 88 may use an insulating material such as tetraethyl ortho silane (TEOS), boro-phospho silicate glass (BPSG), CVD-SiO₂, spin-on glass (SOG), spin-on dielectric (SOD), and the like. However, the material used to fill the spaces of the light emitting nanostructure N is not limited to the insulating protective layer 88. For example, in example embodiments, the spaces between the light emitting nanostructures N may be filled with an electrode element, for example, a reflective electrode material, such as the contact electrode 87.

The nanostructure semiconductor LED chip 80 may include first and second electrodes 89a and 89b. The first electrode 89a may be disposed on an area to which a portion of the base layer 82 formed of a first conductivity-type semiconductor is exposed. In addition, the second electrode 89b may be disposed on an area to which the contact electrode 87 is exposed through extending thereto. The electrode array is not limited thereto, and various electrode arrays may be available according to use conditions.

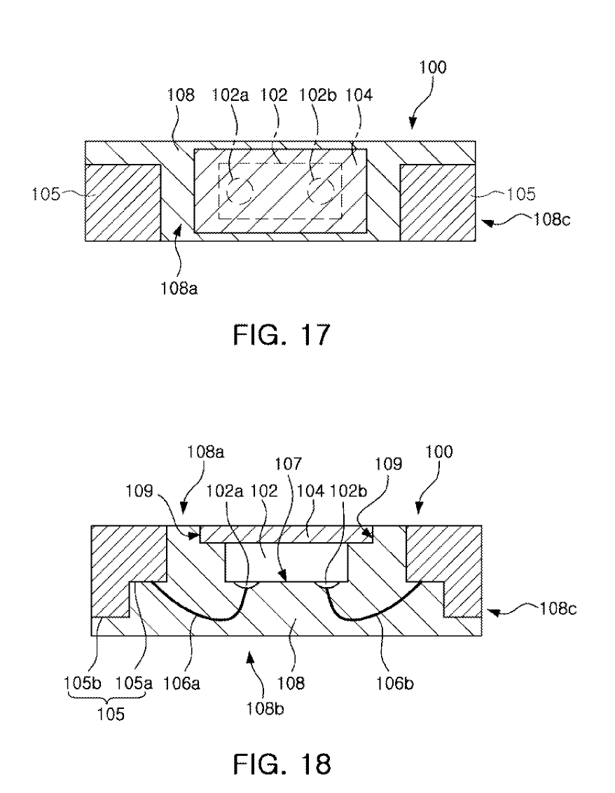

FIGS. 17 and 18 are a top view and a side cross-sectional view each illustrating a semiconductor light emitting device according to an example embodiment in the present disclosure.

Referring to FIGS. 17 and 18, in a manner similar to the above example embodiment, a semiconductor light emitting device 100 may include a package body 108, first and second external terminal blocks 105 disposed on opposite end portions of the package body 108, a wavelength converting material layer 104 disposed between the first and second external terminal blocks 105, and a semiconductor LED chip 102.

The first and second external terminal blocks 105 used in the present example embodiment may have a structure having a step. That is, the external terminal block 105 may be entirely formed of a conductor, and may have a step structure so as to have a surface 105a lower than a reference surface 105b. Such a step difference structure may be formed towards the semiconductor LED chip 102 so as to provide an easy electrical connection to the first and second electrodes 102a and 102b.

In the semiconductor light emitting device 100 according to the present example embodiment, the wavelength converting material layer 104 may have a surface substantially coplanar with a first surface 108a of the package body 108, and may be provided as a light emitting window on the first surface 108a of the package body 108. The package body 108 may have a recess 107 which may be recessed from the first surface 108a of the package body 108 and accommodate the LED chip 102 and the wavelength converting material layer 104. First and second sidewalls 109 of the recess 107 may be disposed between the first and second external terminal blocks 105 and the wavelength converting material layer 104, respectively. Accordingly, since side surfaces of the wavelength converting material layer 104 are not exposed from the package body 108, light leakage may be prevented.

FIG. 19 is a view illustrating a state in which the semiconductor light emitting device illustrated in FIG. 1 is mounted on a circuit substrate.

Referring to FIG. 19, the semiconductor light emitting device 10 illustrated in FIG. 1 may be mounted on a circuit substrate 201. The circuit substrate 201 may have first and second electrode patterns 204a and 204b, and the first and second electrode patterns 204a and 204b may be connected to electrical connection parts 15b of the first and second external terminal block 15 by solders 202a and 202b, respectively.

As such, the external terminal block 15 of the semiconductor light emitting device 10 may include the insulating block body 15a, and the electrical connection part 15b having a form similar to that of a via structure penetrating through the first and second surfaces of the external terminal block 15. The electrical connection part 15b may be exposed through two adjacent side surfaces of the package body 18. In particular, since the side surfaces of the respective first and second external terminal blocks 15 to which the electrical connection parts 15b are exposed, respectively, are disposed on the same surface of the package body 18, two electrical connection parts 15b may be connected to the first and second electrode patterns 204a and 204b disposed on the circuit substrate, respectively. As illustrated in FIG. 19, the semiconductor light emitting device 10 according to the present example embodiment may be provided in a side-view type LED package structure. However, the structure of the semiconductor light emitting device 10 is not limited thereto, and the semiconductor light emitting device 10 may also have a different mounting structure by exposing the electrical connection part of the external terminal block to the second surface or another surface of the package body. For example, even in a case in which the electrical connection parts of the first and second external terminal blocks are disposed on a surface not coplanar with a surface of the package body and are disposed on another surface of the package body, the electrical connection parts may be electrically/mechanically connected using solders.

As such, the semiconductor light emitting device according to the example embodiment described above may be efficiently applied to various application products.

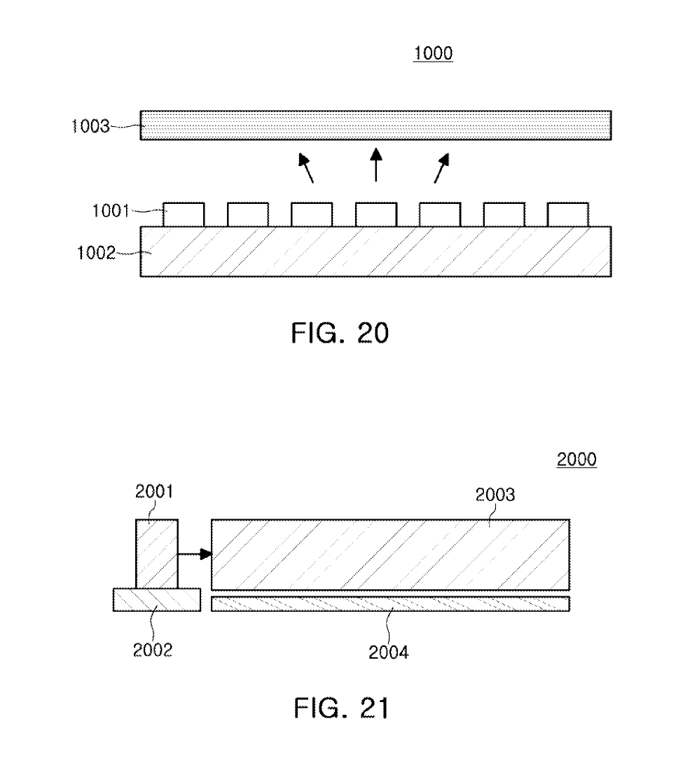

FIGS. 20 and 21 are cross-sectional views illustrating examples of backlight units using semiconductor light emitting devices according to example embodiments in the present disclosure.

Referring to FIG. 20, a back light unit 1000 may include a light source 1001 mounted on a substrate 1002, and at least one optical sheet 1003 disposed thereabove. As the light source 1001, the aforementioned semiconductor light emitting device may be used.

The light source 1001 in the back light unit 1000 illustrated in FIG. 20 may emit light upwardly in a direction in which a liquid crystal display (LCD) device is disposed. However, in a back light unit 2000 of another example illustrated in FIG. 21, a light source 2001 mounted on a substrate 2002 may emit light in a lateral direction such that the emitted light may be incident onto a light guiding panel 2003 to be converted into a form of a surface light source. Light, having passed through the light guiding panel 2003, may be dissipated upwardly, and a reflective layer 2004 may be disposed below the light guiding panel 2003 to improve light extraction efficiency.

FIG. 22 is an exploded perspective view illustrating an example of a lighting apparatus using a semiconductor light emitting device according to an example embodiment.

A lighting apparatus 3000 illustrated in FIG. 22 is illustrated as a bulb-type lamp by way of example, and may include a light emitting module 3003, a driving unit 3008, and an external connection unit 3010.

In addition, the lighting apparatus 3000 may further include an outer structure such as an external housing 3006, an internal housing 3009, and a cover unit 3007. The light emitting module 3003 may include a light source 3001, for example, the aforementioned semiconductor light emitting device, and a circuit substrate 3002 on which the light source 3001 is mounted. In the present example embodiment, an example in which a single light source 3001 is mounted on the circuit substrate 3002 is exemplified; however, as necessary, a plurality of light sources may be mounted thereon.

The external housing 3006 may serve as a heat dissipation unit, and may include a heat dissipation plate 3004 indirect contact with the light emitting module 3003 to enhance heat dissipation effect, and heat dissipation fins 3005 surrounding a side surface of the lighting apparatus 3000. The cover unit 3007 may be mounted on the light emitting module 3003, and may have a convex lens shape. The driving unit 3008 may be installed in the internal housing 3009, and may be connected to the external connection unit 3010 such as a socket structure to be supplied with power externally.

Also, the driving unit 3008 may serve to convert power into an appropriate current source for driving the semiconductor light emitting device, that is, the light source 3001, of the light emitting module 3003, and may provide the converted current source. For example, the driving unit 3008 may be configured of an alternating current-direct current (AC-DC) converter, or a rectifier circuit component.

FIG. 23 is a view illustrating an example of a headlamp using a semiconductor light emitting device according to an example embodiment in the present disclosure.

Referring to FIG. 23, a headlamp 4000 to be employed as a vehicle light, or the like, may include a light source 4001, a reflection unit 4005, and a lens cover unit 4004. The lens cover unit 4004 may include a hollow guide part 4003 and a lens 4002. The light source 4001 may include the aforementioned semiconductor light emitting device or the package including the same.

The headlamp 4000 may further include a heat dissipation unit 4012 externally dissipating heat generated in the light source 4001. The heat dissipation unit 4012 may include a heat sink 4010 and a cooling fan 4011 to effectively dissipate heat. Also, the headlamp 4000 may further include a housing 4009 for allowing the heat dissipation unit 4012 and the reflection unit 4005 to be fixed thereto and supported thereby. The housing 4009 may include having a center hole 4008 formed in one surface thereof, to which the heat dissipation unit 4012 is coupled thereto and mounted thereon.

Additionally, the housing 4009 may include a forwardly open hole 4007 formed in one surface thereof integrally connected to the other surface thereof and bent in a direction perpendicular thereto. The reflection unit 4005 may be fixed to the housing 4009, such that light generated in the light source 4001 may be reflected by the reflection unit 4005, may pass through the forwardly open hole 4007, and may be dissipated externally.

As set forth above, according to example embodiments in the present disclosure, effective light efficiency of the semiconductor light emitting device may be significantly increased in a desired direction through prevention of light leakage by inserting a wavelength converting material layer into an interior of a package body rather than a surface thereof so as not to expose side surfaces of the wavelength converting material layer.

Various advantages and effects in example embodiments in the present disclosure are not limited to the above-described descriptions and may be easily understood through explanations of concrete embodiments in the present disclosure.

While example embodiments have been shown and described above, it will be apparent to those skilled in the art that modifications and variations could be made without departing from the scope of the present invention as defined by the appended claims.

What is claimed is:

1. A semiconductor light emitting device, the device comprising:
a package body having first and second surfaces being opposed to each other, and a plurality of side surfaces disposed therebetween;
first and second external terminal blocks disposed in opposite end portions of the package body, respectively, and each having a portion exposed to surfaces of the package body;
a wavelength converting material layer disposed between the first and second external terminal blocks, and having a first surface substantially coplanar with the first surface of the package body, and a second surface opposing the first surface of the wavelength converting material layer; and
a semiconductor light emitting diode (LED) chip disposed between the first and second external terminal blocks within the package body, disposed on at least a portion of the second surface of the wavelength converting material layer, and electrically connected to the first and second external terminal blocks.

2. The device of claim 1, wherein the package body includes a transparent resin substance containing high reflectivity particles.

3. The device of claim 2, wherein the high reflectivity particles include at least one selected from the group consisting of titanium oxide (TiO₂), aluminum oxide (Al₂O₃), niobium oxide (Nb₂O₅), and zinc oxide (ZnO).

4. The device of claim 1, wherein the wavelength converting material layer contains a phosphor or a quantum dot (QD).

5. The device of claim 1, wherein the wavelength converting material layer is a sintered body film formed of a ceramic phosphor.

6. The device of claim 1, wherein the wavelength converting material layer has a plate shape having a predetermined thickness.

7. The device of claim 1, wherein side surfaces of the semiconductor LED chip are encapsulated by the package body.

8. The device of claim 1, wherein the first and second external terminal blocks each have a first surface exposed to the first surface of the package body, a second surface opposing the first surface of the external terminal block and disposed within the package body, and side surfaces disposed between the first and second surfaces of the external terminal block and having at least one thereof exposed to the side surface of the package body.

9. The device of claim 8, wherein the first and second external terminal blocks each include an insulating block body, and a conductive via passing through first and second surfaces of the insulating block body and disposed on the exposed side surface of the external terminal block.

10. The device of claim 8, wherein the exposed side surfaces of the respective external terminal blocks are disposed on the same surface of the package body.

11. The device of claim 8, wherein a connector of each of the first and second external terminal blocks further includes an electrode layer disposed on the first surface of the insulating block body and connected to the conductive via.

12. The device of claim 1, wherein the semiconductor LED chip and the external terminal block are connected to one another by a wire, and the wire is disposed within the package body.

13. The device of claim 1, wherein the first, second and, side surfaces of the package body are provided in a parallelepipedal structure having six planes.

14. The device of claim 1, wherein the semiconductor LED chip is a blue LED chip, and the wavelength converting material layer is configured so as to emit white light as final light.

15. A semiconductor light emitting device, the device comprising:
a reflective package body having first and second surfaces opposed to each other, and a plurality of side surfaces disposed therebetween;
first and second external terminal blocks disposed on opposite end portions of the package body, respectively, and each having a portion exposed to surfaces of the package body;
a semiconductor light emitting diode (LED) chip disposed between the first and second external terminal blocks within the package body, and electrically connected to the first and second external terminal blocks; and
a wavelength converting material layer having a plate shape having an area greater than an area of the semiconductor LED chip, and having a surface substantially coplanar with the first surface of the package body so as to be exposed through the first surface of the package body, the semiconductor LED chip being interposed between the wavelength converting material layer and the package body.

16. A semiconductor light emitting device, the device comprising:
a semiconductor light emitting diode (LED) chip;
a wavelength converting material layer disposed on the LED chip;
a package body having a recess which is recessed from a first surface of the package body and accommodates the LED chip and the wavelength converting material layer, a surface of the wavelength converting material layer and the first surface of the package body being substantially coplanar with each other; and
first and second external terminal blocks disposed in opposite end portions of the package body and electrically connected to first and second electrodes of the LED chip, respectively,
wherein first and second sidewalls of the recess are disposed between the first and second external terminal blocks and the wavelength converting material layer, respectively.

17. The device of claim 16, wherein the package body includes a lateral surface intersected by the first surface of the package body, and
wherein the lateral surface and external surfaces of the first and second external terminal blocks are substantially coplanar with each other.

18. The device of claim 16, wherein the first and second external terminal blocks are flush to opposite ends of the package body, respectively.

19. The device of claim 18, wherein the first and second external terminal blocks each include a conductive via electrically connected to one of the first and second electrodes of the LED chip, and an insulating block body interposed between the conductive via and one of the first and second sidewalls of the recess.

20. The device of claim 16, wherein the package body includes a transparent resin substance containing high reflectivity particles.
